(19) United States
(12) Patent Application Publication
(10) Pub. No.: US 2004/0265704 A1
(43) Pub. Date: Dec. 30, 2004

(54) Multiple-exposure defect elimination

(75) Inventors: Shih-Ming Chang, Hsinchu (TW); Chih-Cheng Chin, Chunghe City (TW); Wen-Chuan Wang, Taipei (TW); Chi-Lun Lu, Hsinchu (TW); Sheng-Chi Chin, Hsinchu (TW); Chin-Hsiang Lin, Kaohsiung (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/606,823

(22) Filed: Jun. 26, 2003

(51) Int. Cl. G03F 9/00

(52) U.S. Cl. 430/5

(57) ABSTRACT

A multiple-exposure defect elimination process for semiconductor devices being fabricated on semiconductor wafers using photomask parts, including one mask part that is defective, is disclosed. A semiconductor wafer is exposed to a first mask part that is at least partially defective, and then is exposed to a second mask part corresponding to the first mask part but that is at least substantially free from defects or with defects at different locations. The mask parts may be on the same or different photomasks, and have the same layout for a semiconductor device that is being fabricated. Furthermore, the semiconductor wafer may be exposed to the second or other additional mask parts one or more additional times.

### FIELD OF THE INVENTION

This invention relates generally to semiconductor device fabrication, and more particularly to semiconductor photolithography, or the exposure of semiconductor wafers to light through photomasks.

### BACKGROUND OF THE INVENTION

A common process in the fabrication of semiconductor devices on semiconductor wafers is photolithography. In photolithography, the semiconductor wafer is exposed to a light source, such as ultraviolet (UV) light, through a photomask. The photomask, or mask, typically has a number of copies of the layout for the semiconductor device being fabricated. One type of mask is the reticle, which is usually limited to only a single copy of the layout for the device. However, the terms mask, photomask, and reticle are used synonymously within this patent application.

After exposure to the light source, the semiconductor wafer can then be developed. This means that the wafer is exposed to a chemical, usually within a chemical bath, to remove or etch away those parts of the semiconductor wafer that were exposed through the mask. Because the layout of the device being fabricated is on the mask, the exposure of the wafer through the mask means that not all parts of the wafer are exposed to the light source. Thus, the wafer is exposed to the light source in a pattern corresponding to the layout on the mask, and developing the wafer thereafter removes those parts of the wafer that were exposed. Alternatively, development of the wafer may remove those parts thereof that were not exposed.

Defects on the photomask therefore will be transmitted to the semiconductor wafers on which the semiconductor devices are being fabricated. This means that the devices being fabricated on the wafers may be defective, limiting yield. A defective mask means a mask with opaque particles, transmittance errors, phase errors, local CD (critical dimension) errors or global uniformity errors. Because semiconductor device fabrication, and indeed photomask fabrication, are such expensive processes, inspection and repair of photomasks have become important to increase mask yield, and thus also semiconductor device yield. There are many different ways photomasks can be repaired to ensure that they properly transmit their device layouts to semiconductor wafers during photolithography.

However, some photomasks are more difficult to repair, and some types of defects of masks are more difficult to repair. For instance, a phase-shift masks (PSM's) is more difficult to repair. Masks of higher grade also usually suffer more serious defects than lower grade ones. The inspection and repair of masks have also become more difficult, if not impossible, on masks for electron projection lithography (EPL) and on multi-layer reflection masks for extreme ultraviolet (EUV) lithography. This means that yield is decreased for such masks, and for the semiconductor devices that are fabricated using such masks, which can be expensive and time-consuming for the manufacturer or foundry. For this and other reasons, there is a need for the present invention.

### SUMMARY OF THE INVENTION

The invention relates to a multiple-exposure defect elimination process for semiconductor devices being fabricated on semiconductor wafers using photomask parts, including one or more mask parts that are defective. A method of the invention includes exposing a semiconductor wafer to a first mask part that is at least partially defective, and exposing the semiconductor wafer to a second mask part corresponding to the first mask part but that is at least substantially free from defects or with defects at different locations. The mask parts may be on the same or different photomasks, and have the same layout for a semiconductor device that is being fabricated. Furthermore, the method may include exposing the semiconductor wafer to the second mask part one or more additional times.

Embodiments of the invention provide for advantages not found within the prior art. Exposing the wafer to the first mask part that is defective yields a defective image of the device on the wafer. However, one or more successive exposures of the wafer to the second or other additional mask parts that are not defective, or with defects at different locations, substantially eliminate the defects from the device image on the wafer. Generally, the more exposures of the wafer that are made through the non-defective or defective second or other additional mask parts, the more the defects of the image of the device on the wafer are eliminated. Thus, a defective mask part can still be utilized in photolithography and semiconductor fabrication, without having to be repaired. Still other aspects, embodiments, and advantages of the invention will become apparent by reading the detailed description that follows, and by referring to the accompanying drawings.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1 is a flowchart of a method to accomplish multiple-exposure defect elimination, according to an embodiment of the invention.

FIG. 2 is a diagram of a single photomask having a defective mask part of a device layout and a non-defective mask part of a device layout, according to an embodiment of the invention.

FIG. 3 is a diagram of a pair of photomasks of the same device layout, one mask being defective and one mask being non-defective, according to an embodiment of the invention.

FIG. 4 is a diagram of an example exposure through a non-defective mask and an example exposure through a defective mask, according to an embodiment of the invention.

FIG. 5 is a diagram of an example exposure through a non-defective mask and an example exposure through a defective mask followed by an exposure through a non-defective mask, according to an embodiment of the invention.

FIG. 6 is a diagram of an example exposure through a non-defective mask and an example exposure through a defective mask followed by three exposures through a non-defective mask, according to an embodiment of the invention.

### DETAILED DESCRIPTION OF THE DRAWINGS

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

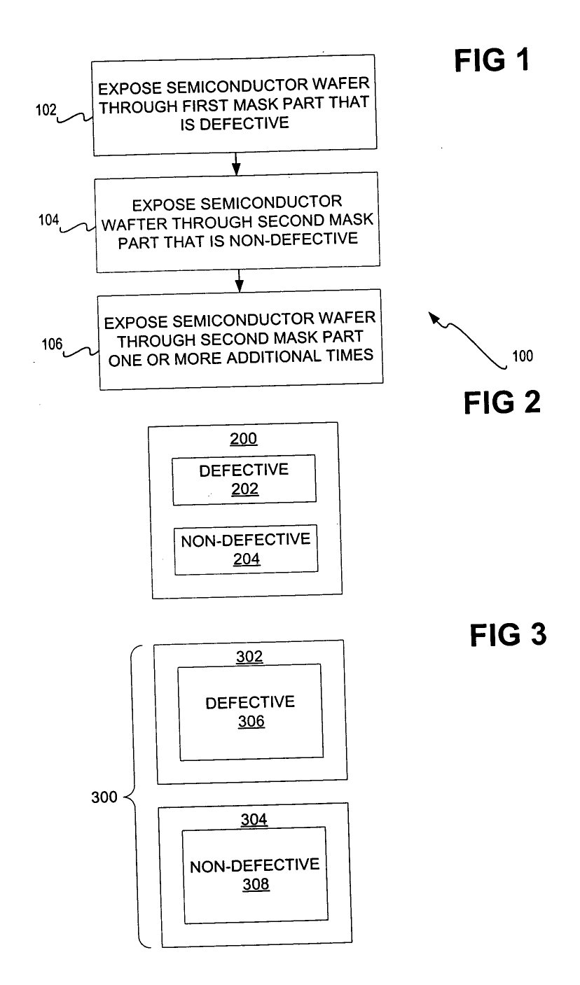

FIG. 1 shows a method 100 of a defect-eliminating double exposure process, according to an embodiment of the invention. The method 100 may be part of a semiconductor fabrication process, such as lithography, that is used to fabricate a semiconductor device or devices on a semiconductor wafer. That is, a semiconductor device may be fabricated at least in part by performing the method 100. As part of lithography, the method 100 is inclusive of the exposure process of lithography. Prior to exposure, alignment is accomplished, such that a mask is aligned over the semiconductor wafer. Subsequent to exposure, development occurs, so that the semiconductor device layout of the mask appears in the semiconductor wafer.

First, a semiconductor wafer is exposed through a first mask part that is defective (102). The first mask part includes a layout for a semiconductor device that is at least partially defective. The semiconductor device is thus to be fabricated on the semiconductor wafer. Next, the semiconductor wafer is exposed through a second mask part that is non-defective (104). The second mask part includes the same layout for the semiconductor device as the first mask part, but the second mask part is at least substantially free from defects.

Finally, the semiconductor wafer is optionally exposed through the second mask part one or more additional times (106). For instance, in one embodiment the semiconductor wafer may be exposed through the second mask part only one additional time. In another embodiment, the semiconductor wafer may be exposed through the second mask part two or three additional times.

The photomask parts utilized in the method 100 may be on the same photomask, or on separate masks. For instance, FIG. 2 shows a representative mask 200, according to an embodiment of the invention. The mask 200 includes a defective mask part 202 and a non-defective mask part 204. Each of the parts 202 and 204 have the same layout for a semiconductor device, but the mask part 202 is defective whereas the mask part 204 is non-defective.

As another example, FIG. 3 shows a pair of representative masks 300, according to an embodiment of the invention. The masks 300 includes a first mask 302 that has a layout area 306, and a second mask 304 that has a layout area 308. The first mask 302 is defective, whereas the second mask 304 is non-defective or defective. The layout areas 306 and 308 are otherwise the same layout for a semiconductor device. Thus, inasmuch as there is only one layout area in each of the masks 302 and 304, the masks 302 and 304 are each only for fabrication of a single semiconductor device.

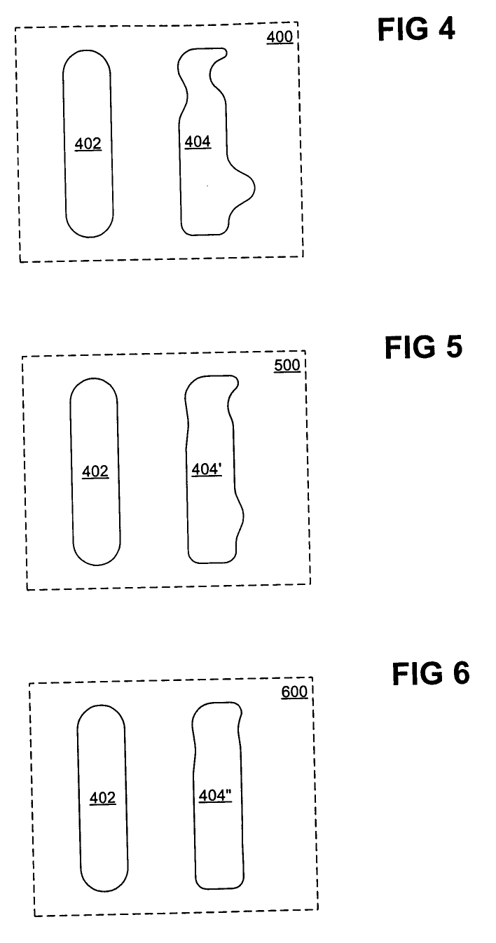

FIGS. 4, 5, and 6 show representative exposures on a semiconductor wafer that can be accomplished in conjunction with the method 100, according to varying embodiments of the invention. In FIG. 4, the exposures 400 include a first semiconductor device exposure 402 on a semiconductor wafer that resulted from exposing the wafer to a light source through a photomask part that was defect-free or with defects at different locations. The exposure 402 is provided for reference purposes. By comparison, the exposures 400 also include a second semiconductor device single exposure 404 on a semiconductor wafer that resulted from exposing the wafer to a light source through a photomask part that had defects. That is, the exposure 404 should look like the exposure 402, but because the mask that was utilized was defective, it is malformed.

In FIG. 5, the exposures 500 again include the first exposure 402 for reference purposes, but the double exposure 404′ results from a double-exposure process. The first exposure was from exposing the wafer through a photomask part that had defects, whereas the second exposure was from exposing the wafer through a corresponding photomask part that did not have any defects or has defects at different locations. That is, the double exposure 404′ is the single exposure 404 of FIG. 4, with an additional exposure through a defect-free or defective mask, such as the mask that was used to result in the first exposure 402. As can be seen by comparing the single exposure 404 of FIG. 4 with the double exposure 404′ of FIG. 5, the additional exposure through the defect-free or defective masks make the double exposure 404′ look more like the exposure 402, at least more so than the single exposure 404 does.

In FIG. 6, the exposure 600 again includes the first exposure 402 for reference exposure, but the quadruple exposure 404″ results from a four-exposure process. The first exposure was from exposing the wafer through a photomask part that had defects. The second, third, and fourth exposures were from exposing the wafer through a corresponding photomask part that did not have any defects or has defects at different locations. That is, the quadruple exposure 404″ is the single exposure 404 of FIG. 4, with three additional exposures through a defect-free mask. The quadruple exposure 404″ is also the double exposure 404′ of FIG. 5, with two additional exposures through a defect free mask. As can be seen by comparing the single exposure 404 of FIG. 4 with the quadruple exposure 404″ of FIG. 6, the additional exposures through the defect-free mask make the quadruple exposure 404″ look more like the exposure 402. Furthermore, as can be seen by comparing the double exposure 404′ of FIG. 5 with the quadruple exposure 404″ of FIG. 6, the three additional exposures through the defect-free mask make the quadruple exposure 404″ look more like the exposure 402 than the double exposure 404′ does.

It is noted that, although specific embodiments have been illustrated and described herein, it will be appreciated by those of ordinary skill in the art that any arrangement is calculated to achieve the same purpose may be substituted for the specific embodiments shown. This application is intended to cover any adaptations or variations of the present invention. Therefore, it is manifestly intended that this invention be limited only by the claims and equivalents thereof.

1. A method comprising:
exposing a semiconductor wafer to a first mask part that is at least partially defective; and,
exposing the semiconductor wafer to a second mask part corresponding to the first mask part and that is at least substantially free from defects or with defects at different locations.

2. The method of claim 1, wherein the first mask part and the second mask part are on a same photomask.

3. The method of claim 1, wherein the first mask part and the second mask part are on different photomasks.

4. The method of claim 1, further comprising exposing the semiconductor wafer to the second mask part a second time.

5. The method of claim 4, further comprising exposing the semiconductor wafer to the second mask part a third time.

6. The method of claim 1, further comprising exposing the semiconductor wafer to the second mask part one or more additional times.

7. The method of claim 1 further comprising exposing the semiconductor wafer to the second, a third and other additional mask parts one or more additional times.

8. The method of claim 1, wherein the first mask part comprises a layout for a semiconductor device that is at least partially defective, and the second mask part comprises a layout for the semiconductor device that is at least substantially free from defects or with defects at different locations.

9. The method of claim 1, wherein exposing the semiconductor wafer to the first mask part and exposing the semiconductor wafer to the second mask part are part of a lithographic semiconductor fabrication process.

10.-23. (Cancelled)
